(19) United States
(12) Patent Application Publication
(10) Pub. No.: US 2018/0158382 A1
(43) Pub. Date: Jun. 7, 2018

(54) INFORMATION TRANSMITTING APPARATUS

(71) Applicant: SHARP KABUSHIKI KAISHA, Sakai City, Osaka (JP)

(72) Inventors: Tomohisa YOSHIE, Sakai City (JP); Satoshi SHIBATA, Sakai City (JP); Shunpei YAMANAKA, Sakai City (JP); Ryohsuke YAMANAKA, Sakai City (JP)

(21) Appl. No.: 15/569,968

(22) PCT Filed: Feb. 24, 2016
(86) PCT No.: PCT/JP2016/055316

§ 371 Date: Oct. 27, 2017

(30) Foreign Application Priority Data
Apr. 27, 2015 (JP) 2015-090806

(51) Int. Cl. G09F 19/00; G09F 7/00; H01L 31/055; G06Q 30/02

(52) U.S. Cl. CPC G09F 19/00; G06Q 30/0268; H01L 31/055; G09F 7/00

(57) ABSTRACT

Product related information desired by a customer is caused to be preferentially acquired by the customer even when a part of light incident on a POP advertisement is blocked by the customer. An information transmitting apparatus (1) includes a transmitting unit that transmits the product related information as a radio signal; a fluorescent concentrating plate (11) that emits fluorescent light upon reception of incident light from both surfaces of at least a front surface and a back surface and guides the fluorescent light; and a solar cell (13) that provides the transmitting unit with power generated upon reception of the fluorescent light. The fluorescent concentrating plate (11) functions as at least a part of a POP advertisement for a product and the solar cell (13) is arranged at an end of the fluorescent concentrating plate (11) so as to be able to receive the fluorescent light.

### TECHNICAL FIELD

The present invention relates to an information transmitting apparatus.

### BACKGROUND ART

In general, advertisement content of a product is printed on an advertising medium such as a poster. Additionally, with the spread of a mobile terminal such as a smartphone, information (information related to a product, also referred to as product related information) such as a website address is often included in the advertisement content. Thus, various measures have been recently taken to directly distribute product related information from an advertising medium to a mobile terminal.

For example, PTL 1 discloses an advertisement information transmitting apparatus (advertisement information transmitting sheet) that is attached on an advertising medium and transmits advertisement information (product related information) in response to a request from a mobile terminal. The advertisement information transmitting apparatus of PTL 1 uses a solar cell as a power source.

### CITATION LIST

### Patent Literature

PTL 1: Japanese Unexamined Patent Application Publication No. 2002-258788 (published on Sep. 11, 2002)

### SUMMARY OF INVENTION

### Technical Problem

In PTL 1, as an advertising medium to which the advertisement information transmitting apparatus is to be applied, an advertising medium having a relatively large size, such as a poster, is assumed. That is, a configuration for a case where the advertisement information transmitting apparatus is applied to an advertising medium having a relatively small size is not particularly considered in PTL 1.

However, depending on a form of a product advertisement, a POP (Point of Purchase) advertisement needs to be used as the advertising medium in some cases. The POP advertisement is an advertising medium that is mainly used for sales promotion in commercial spaces or the like and that has a relatively small size. An example of the POP advertisement includes a piece of paper on which a catch phrase, descriptions, and the like of the product are printed.

Here, considered is a case where the advertisement information transmitting apparatus of PTL 1 is attached on a POP advertisement. When a customer desires to acquire product related information from the POP advertisement, the customer approaches the POP advertisement to put a mobile terminal close to the POP advertisement.

As a result, when the customer acquires the product related information from the POP, a part of light (for example, illumination light in a commercial space) incident on the POP advertisement is blocked by the customer. Thus, the amount of light incident on a solar cell of the advertisement information transmitting apparatus is reduced. As a result, a disadvantage that the solar cell may not generate sufficient power for transmitting the product related information is caused.

However, PTL 1 does not take any specific configuration into consideration for solving such a disadvantage. Therefore, in an invention according to PTL 1, there arises a problem that it is difficult for the customer to acquire the product related information when a part of the light incident on the POP advertisement is blocked by the customer.

The invention was made for solving the aforementioned problem, and an object thereof is to provide an information transmitting apparatus that is able to cause a customer to preferentially acquire product related information desired by the customer even when a part of light incident on a POP advertisement is blocked by the customer.

### Solution to Problem

In order to solve the aforementioned problems, an information transmitting apparatus according to an aspect of the invention is an information transmitting apparatus that transmits product related information, including: a transmitting unit that transmits the product related information as a radio signal; a fluorescent concentrating plate that emits fluorescent light upon reception of incident light from both surfaces of at least a front surface and a back surface and guides the fluorescent light; and a solar cell that provides the transmitting unit with power generated upon reception of the fluorescent light, in which the fluorescent concentrating plate functions as at least a part of a POP advertisement for a product, and the solar cell is arranged at an end of the fluorescent concentrating plate so as to be able to receive the fluorescent light.

### Advantageous Effects of Invention

With an information transmitting apparatus according to an aspect of the invention, an effect in which a customer is enabled to preferentially acquire product related information desired by the customer even when a part of light incident on a POP advertisement is blocked by the customer is exerted.

### BRIEF DESCRIPTION OF DRAWINGS

In Embodiment 1 of the invention, FIG. 1(a) illustrates an external appearance of an information transmitting apparatus, FIG. 1(b) is an enlarged view of an area A1 in FIG. 1(a), FIG. 1(c) is a front view of a solar cell mount board in the area A1, FIG. 1(d) is a top view of the solar cell mount board in the area A1, and FIG. 1(e) is a bottom view of the solar cell mount board in the area A1.

FIG. 2 illustrates an outline of the information transmitting apparatus according to Embodiment 1 of the invention.

FIG. 3 is a view for explaining an operation of the information transmitting apparatus when a customer puts a mobile terminal close to the information transmitting apparatus in Embodiment 1 of the invention.

FIG. 4 illustrates a case where a plurality of information transmitting apparatuses according to Embodiment 1 of the invention are provided and used as POP advertisements.

FIGS. 5(a) and (b) each illustrates a case where a plurality of information transmitting apparatuses as a comparative example are provided and used as POP advertisements.

FIG. 6 illustrates a schematic configuration of a fluorescent concentrating solar cell.

In Embodiment 2 of the invention, FIG. 7(a)

Illustrates an external appearance of an information transmitting apparatus, FIG. 7(b) is an enlarged view of an area A2 in FIG. 7(a), FIG. 7(c) is a front view of a solar cell mount board in the area A2, FIG. 7(d) is a top view of the solar cell mount board in the area A2, and FIG. 7(e) is a bottom view of the solar cell mount board in the area A2.

FIG. 8 schematically illustrates directivity of intensity of a radio wave emitted from an antenna in Embodiment 2 of the invention.

In Embodiment 3 of the invention, FIG. 9(a) illustrates an external appearance of an information transmitting apparatus, FIG. 9(b) is an enlarged view of an area A3 in FIG. 9(a), FIG. 9(c) is a front view of a solar cell mount board in the area A3, FIG. 9(d) is a top view of the solar cell mount board in the area A3, and FIG. 9(e) is a bottom view of the solar cell mount board in the area A3.

FIG. 10 is a functional block diagram illustrating a configuration of a main part of an information transmitting apparatus according to Embodiment 4 of the invention.

FIG. 11(a) illustrates an example of a temporal change of illuminance of light received by a solar cell and FIG. 11(b) illustrates a temporal change of a transmission interval of a radio wave.

FIG. 12 illustrates a configuration of an information transmitting apparatus according to Embodiment 5 of the invention.

FIG. 13 illustrates a configuration of an information transmitting apparatus according to Embodiment 6 of the invention.

### DESCRIPTION OF EMBODIMENTS

### Embodiment 1

Embodiment 1 of the invention will be described below with reference to FIGS. 1 to 6.

### (Outline of Fluorescent Concentrating Solar Cell)

An information transmitting apparatus 1 of the present embodiment is provided with a fluorescent concentrating solar cell as a power source. First, before giving detailed description for the information transmitting apparatus 1, an outline of the fluorescent concentrating solar cell will be briefly described.

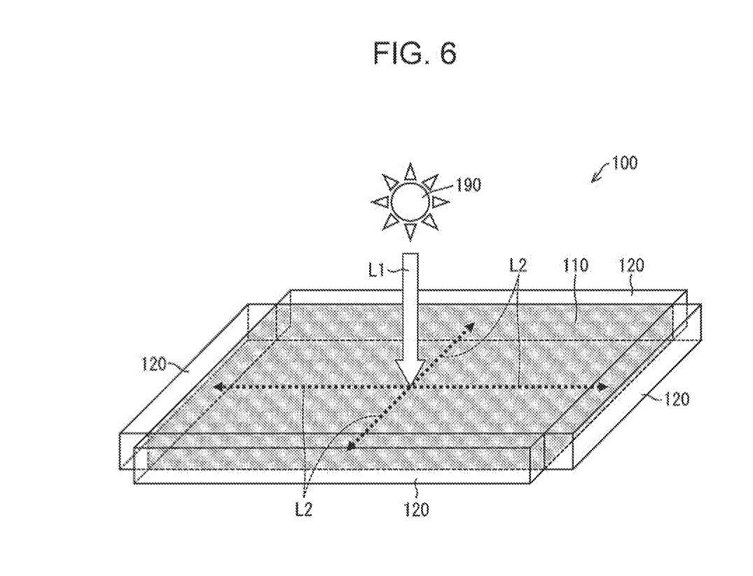

FIG. 6 is perspective view illustrating a schematic configuration of the fluorescent concentrating solar cell. Hereinafter, the fluorescent concentrating solar cell of FIG. 6 is referred to as a fluorescent concentrating solar cell 100. The fluorescent concentrating solar cell 100 includes a fluorescent concentrating plate 110 and solar cells 120. The fluorescent concentrating solar cell 100 is arranged to receive incident light L1 from a light source 190.

FIG. 6 illustrates a case where the fluorescent concentrating solar cell 100 is placed outdoors, as an example. Thus, the light source 190 is the sun and the incident light L1 is sunlight. However, as described below, the fluorescent concentrating solar cell 100 may be placed indoors. Thus, the light source is not limited only to the sun and may be, for example, an illumination device provided indoors.

The fluorescent concentrating plate 110 includes a phosphor excited by the incident light L1. The phosphor absorbs the incident light L1 as excitation light and emits fluorescent light L2 that has a longer wavelength than that of the incident light L1. Thus, the fluorescent concentrating plate 110 functions as a member that receives the incident light L1 and emits the fluorescent light L2. Note that, a known material may be appropriately used as a material of the phosphor in accordance with specifications of the fluorescent concentrating solar cell 100.

As illustrated in FIG. 6, the fluorescent concentrating plate 110 has four side surfaces which are in the form of an oblong rectangle. The solar cell 120 is provided on each of the four side surfaces of the fluorescent concentrating plate 110. However, the number of the side surfaces of the fluorescent concentrating plate 110 may not be always limited to four.

The fluorescent concentrating plate 110 is configured to guide the fluorescent light L2 toward each of the four solar cells 120. As an example, the fluorescent concentrating plate 110 may be manufactured by dispersing a phosphor in a transparent acrylic plate.

Each of the solar cells 120 is a photoelectric conversion element that converts energy of the fluorescent light L2 guided by the fluorescent concentrating plate 110 into electric energy. That is, the solar cell 120 receives the fluorescent light L2 and generates power. The solar cell 120 may be, for example, a known solar cell array.

Note that, the solar cell array means a circuit in which a plurality of solar cell modules are connected in series or in parallel. The solar cell module also means a circuit in which a plurality of solar cells are connected in series or in parallel.

The fluorescent concentrating solar cell 100 mainly has the following advantages (1) to (4).

(1) instead of the solar cell 120, the incident light L1 is able to be received by the fluorescent concentrating plate 110. Thus, an area of the solar cell is able to be reduced compared to a general solar cell panel (non-concentrating solar cell).

Since no additional optical member such as a lens or a reflector is provided other than the fluorescent concentrating plate 110, a solar cell which is thinner and lighter than a concentrating solar cell provided with such an additional optical member is able to be realized.

(2) It is possible to absorb the incident light L1 by the fluorescent concentrating plate 110 and supply the fluorescent light L2 to the solar cell 120. Thus, even when the incident light L1 is not incident almost vertically a light-receiving surface of the fluorescent concentrating plate 110, power generation by the solar cell 120 is able to be performed. Therefore, dependency of a power generation amount on an incident angle of the light incident on the light-receiving surface is able to be reduced compared to the concentrating solar cell provided with the additional optical member as described above.

(3) The incident light is able to be received on any of the surfaces of the fluorescent concentrating plate 110. For example, the incident light is able to be received also on the surface opposite to the surface on which the incident light L1 is received. In this manner, it is possible to perform power generation by the solar cell 12 by receiving the incident light on more various surfaces of the fluorescent concentrating plate 110 compared to the concentrating solar cell provided with the additional optical member as described above.

(4) Therefore, it is possible to improve the flexibility in designing the shape of the fluorescent concentrating plate 110. For example, it is possible to realize the fluorescent concentrating plate 110 in a spherical shape or the fluorescent concentrating plate 110 in a curved shape. The fluorescent concentrating plate 110 is also able to be subjected to processing such as drilling. In any case, the solar cell 120 is only required to be arranged so as to be able to receive the fluorescent light L2 guided by the fluorescent concentrating plate 110.

By focusing on the advantages (1) to (4) described above, a fluorescent concentrating solar cell is adopted as a power source in the information transmitting apparatus 1 of the present embodiment.

### (Information Transmitting Apparatus 1)

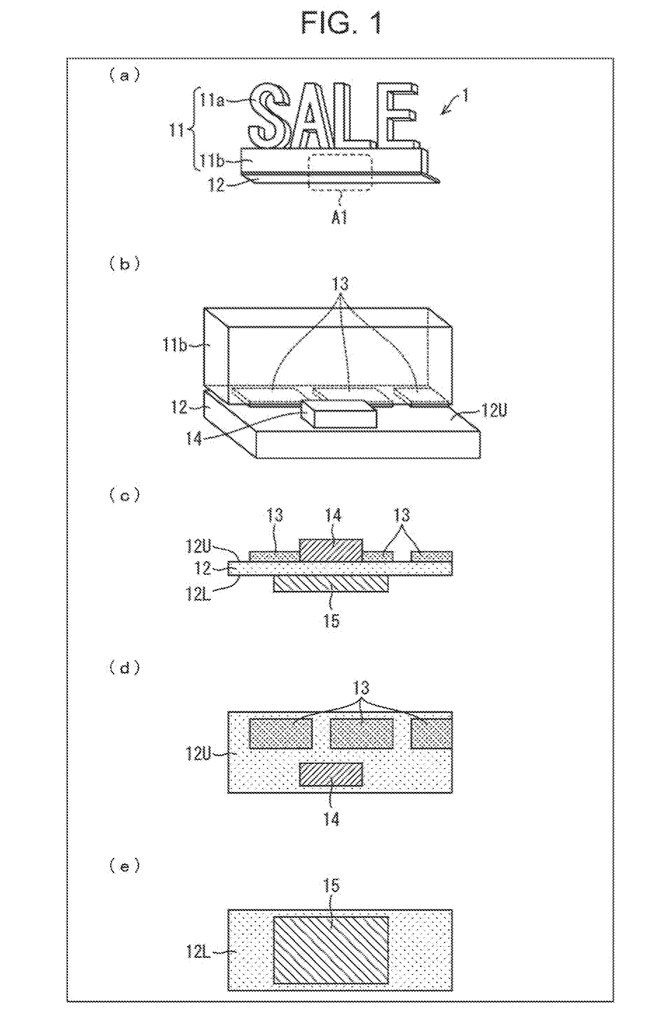

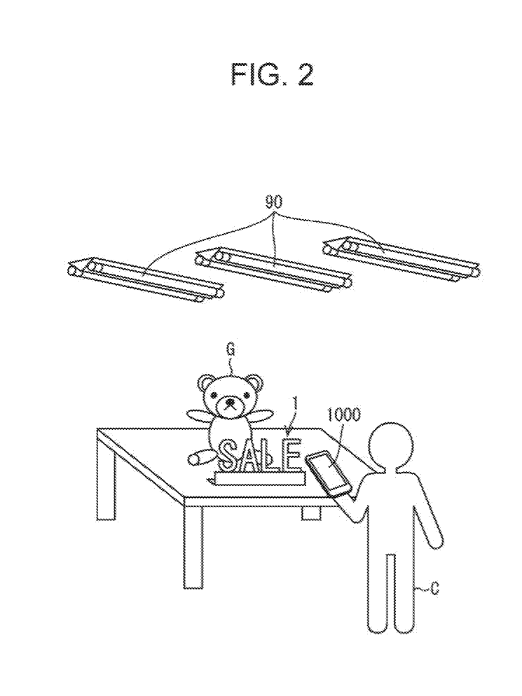

Subsequently, a configuration of the information transmitting apparatus 1 will be described in detail with reference to FIGS. 1 to 3. First, a function of the information transmitting apparatus 1 will be schematically described with reference to FIG. 2. FIG. 2 is a view for explaining an outline of the information transmitting apparatus 1.

Note that, the present embodiment will be described by using a case where the information transmitting apparatus 1 is provided as a POP advertisement for promoting a product G in a commercial space as an example. However, the information transmitting apparatus 1 does not always need to be provided as a whole of the POP advertisement and may be provided as a part of the POP advertisement. That is, the information transmitting apparatus 1 (more specifically, an advertisement part 11a described below) is only required to function as at least a part of the POP advertisement.

The information transmitting apparatus 1 has a function of transmitting, as a radio signal, product related information that is information related to the product G. The product related information may be, for example, an electronic coupon for receiving a discount service of the product G or may be ID data for logging in to a website from which the electronic coupon is able to be downloaded. Note that, the information transmitting apparatus 1 may acquire the product related information in advance from a PC or the like in the commercial space before providing a customer with the product related information.

When a customer C desires to acquire product related information from the information transmitting apparatus 1, the customer C puts a mobile terminal 1000 close to the information transmitting apparatus 1. Thereby, the product related information transmitted from the information transmitting apparatus 1 is able to be received by the mobile terminal 1000.

Note that, as specifically described below, a fluorescent concentrating solar cell is adopted as a power source in the information transmitting apparatus 1. The fluorescent concentrating solar cell is able to perform power generation by converting illumination light emitted from an illumination device 90 in the commercial space into fluorescent light.

FIGS. 1(a) to (e) each illustrate a configuration of the information transmitting apparatus 1. As illustrated in FIGS. 1(a) to (e), the information transmitting apparatus 1 includes a fluorescent concentrating plate 11, a solar cell mount board 12 (mount board), solar cells 13, an antenna 14, and a BLE (Bluetooth (registered trademark) Low Energy) module 15 (modulation unit).

FIG. 1(a) illustrates as external appearance of the information transmitting apparatus 1. As illustrated in FIG. 1(a), the fluorescent concentrating plate 11 has the advertisement part 11a and a non-advertisement part 11b.

Note that, the fluorescent concentrating plate 11 (that is, the advertisement part 11a and the non-advertisement part 11b) of the present embodiment may be formed by cutting out a fluorescent concentrating plate in a plate shape. As described above, the fluorescent concentrating plate 11 (the advertisement part 11a and the non-advertisement part 11b) receives the illumination light emitted from the illumination device 90 and emits the fluorescent light.

The advertisement part 11a is a part that functions at least a part of the POP advertisement in the fluorescent concentrating plate 11. In other words, the advertisement part 11a is a part that forms at least a part of the POP advertisement in the fluorescent concentrating plate 11.

In the present embodiment, the advertisement part 11a is formed to represent characters of “SALE”. However, the advertisement part 11a is only required to have a shape formed so as to function at least a part of the POP advertisement.

The advertisement part 11a may not be formed to always represent only a character. For example, the advertisement part 11a may be formed to represent a shape of an animation character, an animal, or the like.

The non-advertisement part 11b is a part of the fluorescent concentrating plate 11 other than the advertisement part 11a. In the present embodiment, the non-advertisement part 11b has a rectangular shape. The non-advertisement part 11b functions also as a support member that supports the advertisement part 11a.

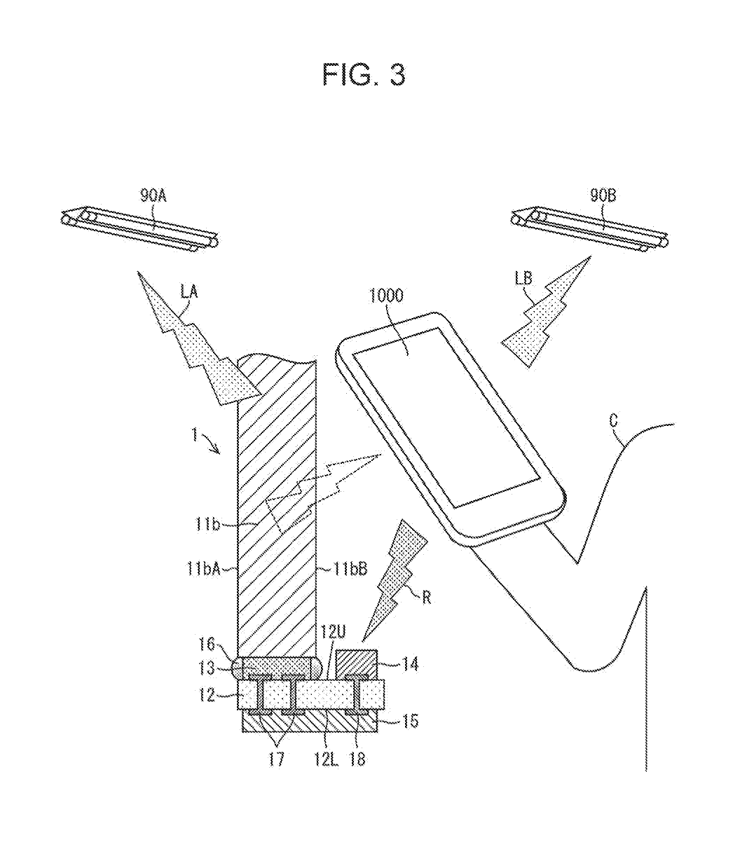

As described below, each of the solar cells 13 is arranged on an end surface (end) of the non-advertisement part 11b (refer to FIG. 3). Here, the end surface of the non-advertisement part 11b means a surface positioned opposite to the advertisement part 11a among a plurality of surfaces of the non-advertisement part 11b. Note that, the end surface of the non-advertisement part 11b is also able to be interpreted as a surface facing the solar cell mount board 12 described below.

FIG. 1(b) is an enlarged view of an area A1 in FIG. 1(a). Next, the solar cell mount board 12 and peripheral members thereof will be described with reference to FIG. 1(b).

The solar cell mount board 12 is a board on which the solar cells 13 are to be arranged. Hereinafter, a surface on which the solar cells 13 are arranged in the solar cell mount board 12 will be referred to as a mount board first surface 12U (first surface).

As illustrated in FIG. 1(b), the mount board first surface 12U faces the end surface of the non-advertisement part 11b. The mount board first surface 12U may be referred to as a top surface of the solar cell mount board 12.

Each of the solar cells 13 may be, for example, a solar cell module. Note that, though a configuration in which a plurality of solar cells 13 is provided is used as an example in the present embodiment, the number of the solar cells 13 may be one.

The fluorescent concentrating plate 11 is constituted so as to guide fluorescent light, which is emitted by the fluorescent concentrating plate 11, toward the solar cells 13 arranged on the mount board first surface 12U. In the present embodiment, the solar cells 13 are arranged on the end surface of the non-advertisement part 11b so as to be able to receive the fluorescent light. That is, the solar cells 13 are arranged between the non-advertisement part 11b and the solar cell mount board 12 so as to contact both the non-advertisement part 11b and the solar cell mount board 12 (also refer to FIG. described below).

By arranging the fluorescent concentrating plate 11 and the solar cells 13 as described above, a fluorescent concentrating solar cell that performs power generation by using illumination light emitted from the illumination device 90 is able to be realized.

As described below, the fluorescent concentrating plate 11 is able to receive the illumination light (incident light) from both surfaces of at least a front surface and a back surface. Accordingly, the advertisement part 11a that functions as at least a part of the POP advertisement is also able to receive the illumination light from both surfaces of at least a front surface and a back surface. Further, the non-advertisement part 11b is also able to receive the illumination light from both surfaces of at least a front surface and a back surface.

Note that, in the present embodiment, the fluorescent concentrating plate 11 is formed so that a surface area of the non-advertisement part 11b is significantly larger than a surface area of the advertisement part 11a. Thereby, the non-advertisement part 11b is able to receive a greater amount of illumination light than the advertisement part 11a, thus making it possible to further increase an amount of the power generated by the solar cells 13.

As illustrated in FIG. 1(b), in addition to the solar cells 13, an antenna 14 (transmitting unit) is arranged on the mount board first surface 12U. Note that, an operation of the antenna 14 will be described below.

FIGS. 1(c) to (e) each illustrates a positional relation of the solar cell mount board 12 and related members in the area A1. Specifically, FIG. 1(c) is a front view of the solar cell mount board 12 in the area A1, FIG. 1(d) is a top view of the solar cell mount board 12 in the area A1, and FIG. 1(e) is a bottom view of the solar cell mount board 12 in the area A1. Note that, for simplification of the illustration, the illustration of the non-advertisement part 11b is omitted in FIGS. 1(c) to (e).

Here, a surface opposite to the aforementioned mount board first surface 12U in the solar cell mount board 12 is referred to as a mount board second surface 12L (second surface). In other words, a lower surface of the solar cell mount board 12 means the mount board second surface 12L.

As illustrated in FIGS. 1(c) and (e), the BLE module 15 (transmitting unit, modulation unit) is arranged on the second surface 12L. As described below, the antenna 14 and the BLE module 15 are members provided for transmitting product related information to the mobile terminal 1000. Thus, the antenna 14 and the BLE module 15 are also referred to as a beacon transmitter (transmitting unit).

The solar cell mount board 12 is also able to be interpreted as a board on which the solar cells 13 and the beacon transmitter are arranged. This is because, as described above, in the solar cell mount board 12, (i) the solar cells 13 and the antenna 14 are arranged on the mount board first surface 12U and (ii) the BLE module 15 is arranged on the mount board second surface 12L.

FIG. 3 is a view for explaining an operation of the information transmitting apparatus 1 when the customer C puts the mobile terminal 1000 close to the information transmitting apparatus 1. In FIG. 3, the configuration of the information transmitting apparatus 1 is illustrated in more detail than FIGS. 1 and 2 described above.

Illumination devices 90A and 90B illustrated in FIG. 3 are similar to the illumination device 90 of FIG. 2. However, for convenience of the description described below, the illumination devices 90A and 90B are distinguished in FIG. 3. In FIG. 3, illumination light emitted from the illumination device 90A is referred to as it light LA (incident light) and illumination light emitted from the illumination device 90B is referred to as illumination light LB (incident light).

FIG. 3 illustrates a case where each of the illumination light LA and LB is directed to the non-advertisement part 11b of the fluorescent concentrating plate 11, as an example. Here, a surface of the non-advertisement part 11b, to which the illumination light LB is directed, is referred to as a non-advertisement part second surface 11bB (front surface). A surface of the non-advertisement part 11b, to which the illumination light LA is directed, is referred to as a non-advertisement part first surface 11bA (back surface).

The non-advertisement part second surface 11bB is a surface facing the mobile terminal 1000 (and the customer C). Thus, the non-advertisement part second surface 11bB may be interpreted as a front surface of the non-advertisement part 11b (or the fluorescent concentrating plate 11).

The non-advertisement part first surface 11bA is a surface opposite to the non-advertisement part second surface 11bB. That is, the non-advertisement part first surface 11bA is a surface not facing the mobile terminal 1000 (or the customer C). The non-advertisement part first surface 11bA may be interpreted as a back surface of the non-advertisement part 11b (or the fluorescent concentrating plate 11).

The fluorescent concentering plate 11 is able to receive illumination light (incident light) from both surfaces of at least the front surface and the back surface. With reference to FIG. 3, the illumination light directed to each of the non-advertisement part second surface 11bB and the non-advertisement part first surface 11bA will be considered below.

According to FIG. 3, when the mobile terminal 1000 is put close to the information transmitting apparatus 1, the illumination light LB directed to the non-advertisement part second surface 11bB serving as the front surface is blocked by the mobile terminal 1000.

Thus, when the mobile terminal 1000 is put close to the information transmitting apparatus 1, the illumination light LB is not able to be incident on the non-advertisement part second surface 11bB. In other words, when the mobile terminal 1000 is put close to the information transmitting apparatus 1, the illumination light LB is not able to be incident on the fluorescent concentrating plate 11.

On the other hand, even when the mobile terminal 1000 is put close to the information transmitting apparatus 1, the non-advertisement part first surface 11bA serving as the back surface does not face the mobile terminal 1000 and is thus able to receive the illumination light LA.

Thus, even when the illumination light LB is not able to be incident on the non-advertisement part second surface 11bB serving as the front surface because of the mobile terminal 1000 being put close to the information transmitting apparatus 1, the illumination light LA is able to be incident on the non-advertisement part first surface 11bA serving as the back surface. As a result, the illumination light is able to be incident on the fluorescent concentrating plate 11, so that power generation by the solar cells 13 is able to be performed.

As described above, according to the information transmitting apparatus 1 of the present embodiment, adopting the fluorescent concentrating solar cell as the power source, even when the mobile terminal 1000 is put close to the information transmitting apparatus 1 (that is, when a part of light incident on the POP advertisement is blocked by the customer C), power generation is able to be performed.

Subsequently, a more detailed configuration of the information transmitting apparatus 1 will be described by continuously referring to FIG. 3. In the information transmitting apparatus 1, the non-advertisement part 11b is adhered to the mount board first surface 12U by an optical adhesion unit 16. Each of the solar cells 13 arranged on the mount board first surface 12U is covered with the optical adhesion unit 16.

The optical adhesion unit 16 may be an adhesive material having predetermined transparent characteristics and adhesiveness. An optical adhesive sheet in a film shape is also able to be used as the optical adhesion unit 16. The optical adhesive sheet is also referred to as an OCA (Optical Clear Adhesive).

By providing the optical adhesion unit 16, a positional relation between the non-advertisement part 11b and the solar cell 13 is able to be fixed and the fluorescent light emitted by the fluorescent concentering plate 11 is able to be incident on the solar cell 13.

As illustrated in FIG. 3, the solar cell mount board 12 provided with (i) a power source wiring 17 by which the solar cell 13 is electrically connected to the BLE module 15 and (ii) an antenna wiring 18 by which the antenna 14 is electrically connected to the BLE module 15. Specifically, each of the power source wiring 17 and the antenna wiring 18 is provided as a wiring passing through the solar cell mount board 12.

The power source wiring 17 is a wiring (power line) for performing transmission of power. By providing the power source wiring 17, the power generated by the solar cell 13 is able to be supplied to the BLE module (in other words, the beacon transmitter). Thus, the beacon transmitter is able to be operated by using the power generated by the solar cell 13.

The antenna wiring 18 is a wiring (communication line) for performing transmission of an information signal. As described below, by providing the antenna wiring 18, product related information is able to be transmitted from the BLE module 15 to the antenna 14.

The BLE module 15 is a module in which members for performing radio communication with use of the Bluetooth (registered trademark) are accumulated. However, means of radio communication according to an aspect of the invention is not always limited only to the Bluetooth (registered trademark) and means based on another radio communication standard may be adopted.

In the present embodiment, the BLE module 15 generates, as a wire signal, a periodic signal (for example, a high frequency signal) that includes the product related information. That is, the BLE module 15 modulates the product related information to the periodic signal. The BLE module 15 then supplies the periodic signal as the wire signal to the antenna 14 via the antenna wiring 18 described above.

The antenna 14 converts the periodic signal as the wire signal that is supplied from the BLE module 15 into a radio signal and transmits the radio signal to the outside of the information transmitting apparatus 1. Specifically, as illustrated in FIG. 3, the antenna 14 transmits, to the mobile terminal 1000, a radio wave R (also referred to as a beacon radio wave) as the radio signal. The radio wave R functions as a carrier wave for conveying the product related information.

By receiving the radio wave R transmitted from the antenna 14 and demodulating the radio wave R, the mobile terminal 1000 is able to acquire the product related information. In other words, it is possible to make an interpretation such that the BLE module 15 transmits the product related information to the mobile terminal 1000 via the antenna 14. Thus, the beacon transmitter (the antenna 14 and the BLE module 15) may be interpreted as a member (transmitting unit) that transmits the product related information as the radio signal.

As described above, in the information transmitting apparatus 1 of the present embodiment, the solar cell 13 and the beacon transmitter (the antenna 14 and the BLE module 15) are provided on the common (same) mount board (that is, the solar cell mount board 12). Thus, widths of the wirings (that is, the power source wiring 17 and the antenna wiring 18) by which the solar cell 13 and the beacon transmitter are connected are able to be made relatively small.

Accordingly, the radio wave R transmitted from the antenna 14 is less likely to be affected by noise of the wirings. This is because when the widths of the wirings are small, the noise from the wrings is reduced.

On the other hand, when the solar cell 13 and the beacon transmitter are not provided on the common mount board, strength of the wirings by which the solar cell 13 and the beacon transmitter are connected needs to be secured. Thus, the widths of the wirings need to be increased compared to a case where the solar cell 13 and the beacon transmitter are provided on the common mount board. As a result, the radio wave R is likely to be affected by the noise from the wirings described above.

In this manner, in the information transmitting apparatus 1 of the present embodiment, by providing both the solar cell 13 and the beacon transmitter on the solar cell mount board 12, the radio wave R is able to be less affected by the noise. Accordingly, intensity of the radio wave R is able to be set to be relatively small.

Additionally, since (i) the mount board on which the solar cell 13 is provided and (ii) the mount board on which the beacon transmitter is provided are able to be used in common, an advantage of allowing reduction in cost of the information transmitting apparatus 1 is also able to be achieved.

### (Additional Effect of Information Transmitting Apparatus 1)

As described above, the fluorescent concentrating solar cell is adopted as the power source in the information transmitting apparatus 1 of the present embodiment. Thus, even when the mobile terminal 1000 is put close to the information transmitting apparatus 1, the illumination light LA is able to be incident on the back surface of the fluorescent concentrating plate 11, thus making it possible to perform power generation by the solar cell 13.

As a result, an effect is exerted that the customer C is enabled to preferentially acquire product related information desired by the customer C even when a part of light incident on the information transmitting apparatus 1 (that is, the POP advertisement) is blocked by the customer C.

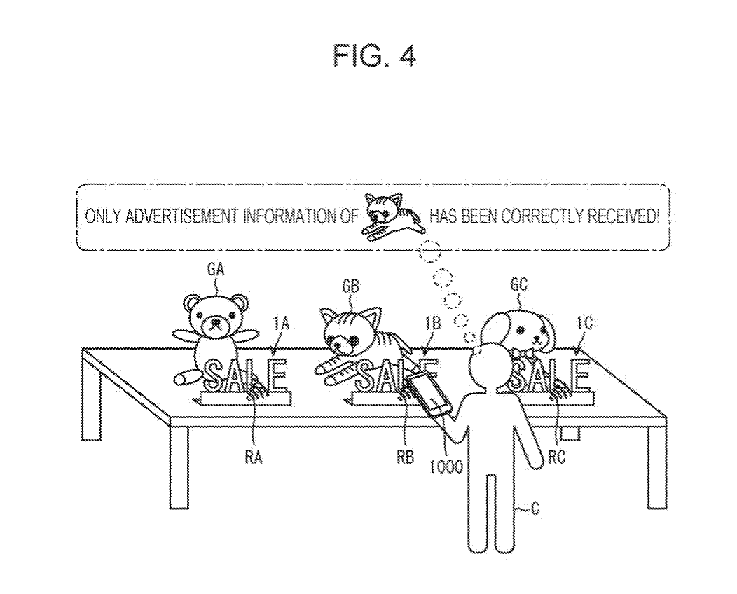

Subsequently, an additional effect of the information transmitting apparatus 1 of the present embodiment will be described with reference to FIG. 4. FIG. 4 illustrates a case where a plurality of information transmitting apparatuses according to the present embodiment are provided and used as POP advertisements.

Note that, FIG. 4 illustrates the case where information (advertisement information) indicating advertisement content of a product is transmitted as product related information, as an example. The advertisement information may be, for example, information indicating a sale period of a product, or the like.

FIG. 4 illustrates the case where three information transmitting apparatuses (an information transmitting apparatus 1A, an information transmitting apparatus 1B, and an information transmitting apparatus 1C) are provided so as to correspond to three products (products GA, GB, and GC), as an example.

In FIG. 4, the three information transmitting apparatuses are referred to as the information transmitting apparatus 1A, the information transmitting apparatus 1B, and the information transmitting apparatus 1C for distinguishing the respective information transmitting apparatuses. Note that, the information transmitting apparatuses 1A to 1C are similar to the information transmitting apparatus 1 described above.

Specifically, the information transmitting apparatus 1A is a POP advertisement for the product GA and transmits a radio wave RA (radio signal). The information transmitting apparatus 1B is a POP advertisement for the product GB and transmits a radio wave RB (radio signal). The information transmitting apparatus 1C is a POP advertisement for the product GC and transmits a radio wave RC (radio signal).

Here, considered is a case where the customer C intends to acquire product related information of the product GB from the information transmitting apparatus 1B. That is, considered is a case where the customer C approaches the information transmitting apparatus 1B and puts the mobile terminal 1000 close to the information transmitting apparatus 1B.

In this case, the information transmitting apparatus 1B is an information transmitting apparatus whose distance from the mobile terminal 1000 is closest as illustrated in FIG. 4. On the other hand, the information transmitting apparatuses 1A and 1C are at positions farther from the mobile terminal 1000 than the information transmitting apparatus 1B.

Thus, the intensity of the radio waves RA and RC is interpreted as being smaller than the intensity of the radio wave RB at the position where the mobile terminal 1000 exists. This is because the intensity of a radio wave generally decreases as a distance from a transmission source of the radio wave is farther.

Meanwhile, as described above, the intensity of the radio waves RA to RC is able to be set to be small to some extent in the information transmitting apparatuses 1A to 1C. As a result, the mobile terminal 1000 is able to acquire the product related information by receiving the radio wave RB transmitted from the information transmitting apparatus 1B serving as the information transmitting apparatus closest to the customer C and demodulating the radio wave RB.

This is because the intensity of the radio waves R and RC is sufficiently smaller than that of the radio wave RB at the position where the mobile terminal 1000 exists. That is, the reason is that even when receiving the radio waves RA and RC, the mobile terminal 1000 is not able to demodulate the radio waves RA and RC and acquire the product related information.

As described above, according to the information transmitting apparatuses 1A to 1C of the present embodiment (that is, the information transmitting apparatus 1), the customer C is enabled to selectively acquire only product related information (product related information transmitted by the radio wave RB) that is intended to be acquired by the customer C.

### COMPARATIVE EXAMPLES

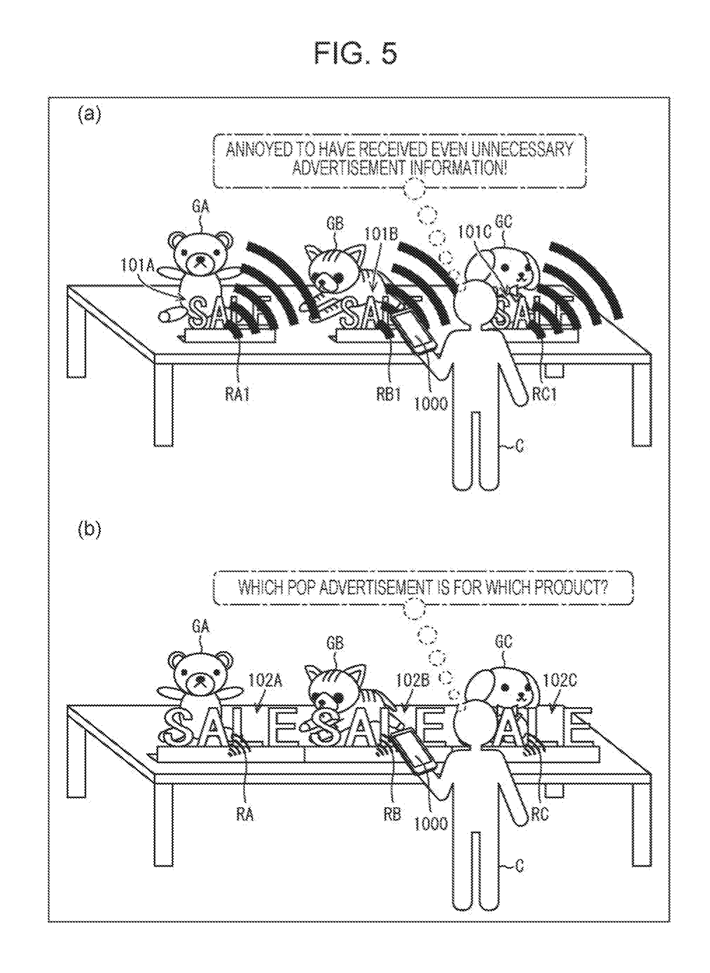

Subsequently, with reference to FIG. 5, comparative examples for describing the effect of the information transmitting apparatus 1 of the present embodiment more specifically will be described in (1) and (2) below.

FIGS. 5(a) and (b) each illustrates a case where a plurality of information transmitting apparatuses as a comparative example are provided and used as POP advertisements. FIGS. 5(a) and (b) may be interpreted as comparative examples of the configuration of FIG. 4 described above.

(1) FIG. 5(a) illustrates a case where information transmitting apparatuses 101A to 101C as a comparative example of the information transmitting apparatuses 1A to 1C of FIG. 4 are used as POP advertisements. Specifically, each of the information transmitting apparatuses 101A to 101C has a configuration obtained by providing the solar cell 13 and the beacon transmitter on individual mount boards in the information transmitting apparatus 1 described above.

In FIG. 5(a), radio waves transmitted from the information transmitting apparatuses 101A to 101C are respectively referred to as radio waves RA1 to RC1. The radio waves RA1 to RC1 are more likely to be affected by the noise than the radio waves RA to RC of FIG. 4 described above. This is because the solar cell 13 and the beacon transmitter are not provided on the common mount board in each of the information transmitting apparatuses 101A to 101C.

Thus, in the information transmitting apparatuses 101A to 101C, the radio wave intensity of the radio waves RA1 to RC1 needs to be set to be great to some extent in order to prevent radio wave failure due to the noise. Thus, the radio wave intensity of the radio waves RA1 to RC1 is not able to be reduced to an extent of the radio wave intensity of the radio waves RA to RC of FIG. 4.

Here, similarly to FIG. 4 described above, a case where the customer intends to acquire the product related information of the product GB from the information transmitting apparatus 101B is considered. That is, a case where the customer C puts the mobile terminal 1000 close to the information transmitting apparatus 101B is considered.

However, in the case of FIG. 5(a), the intensity of the radio waves RA1 and RC1 becomes significantly greater than the intensity of the radio waves RA and RC of FIG. 4 described above at the position where the mobile terminal 1000 exists.

As a result, the mobile terminal 1000 receives the radio waves RA1 and RC1 having relatively great radio wave intensity. Therefore, product related information (product related information transmitted by the radio waves RA1 and RC1) that is not intended to be acquired by the customer C is acquired in the mobile terminal 1000.

That is, the information transmitting apparatuses 101A to 101C of the comparative example have a problem that the customer C is not enabled to selectively acquire only the product related information that is intended to be acquired by the customer C.

However, according to the information transmitting apparatuses 1A to 1C of the present embodiment, as illustrated in FIG. 4 described above, the problem caused in the information transmitting apparatuses 101A to 101C of the comparative example is able to be solved.

(2) FIG. 5(b) illustrates a case where information transmitting apparatuses 102A to 102C as another comparative example of the information transmitting apparatuses 1A to 1C of FIG. 4 are used as POP advertisements. Specifically, each of the information transmitting apparatuses 102A to 102C has a configuration obtained by adopting a solar cell of a different type from that of the fluorescent concentrating solar cell as the power source in the information transmitting apparatus 1 described above.

Since the fluorescent concentrating solar cell is not adopted as the power source in each of the information transmitting apparatuses 102A to 102C, a concentrating plate by which illumination light is incident on the solar cell is provided instead of the fluorescent concentrating plate 11.

Thus, in order for sufficient illumination light to be incident on the solar cell even when the customer C approaches the information transmitting apparatuses 102A to 102C, a size of the concentrating plate needs to be significantly greater than that of the fluorescent concentering plate 11.

Thus, as illustrated in FIG. 5(b), the sizes of the information transmitting apparatuses 102A to 102C are significantly greater than those of the information transmitting apparatuses 1A to 1C of FIG. 4 described above. Accordingly, the sizes of the information transmitting apparatuses 102A to 102C are excessively great with respect to the products GA to GC.

Therefore, when a sufficient space where the information transmitting apparatuses 102A to 102 are installed is not secured, is difficult for the information transmitting apparatuses 102A to 102C to be arranged to be sufficiently separated from each other so as to correspond to the products GA to GC.

As described above, the information transmitting apparatuses 102A to 102C of the comparative example have a problem that the customer C is not able to easily recognize the POP advertisement from which desired product related information is able to be acquired.

However, according to the information transmitting apparatuses 1A to 1C of the present embodiment, since the fluorescent concentrating solar cell is adopted as the power source of each of the information transmitting apparatuses as described above, a size of the fluorescent concentrating plate 11 is able to be reduced. Thus, according to the information transmitting apparatuses 1A to 1C of the present embodiment, the aforementioned problem caused in the information transmitting apparatuses 102A to 102C of the comparative example is also able to be solved.

### Embodiment 2

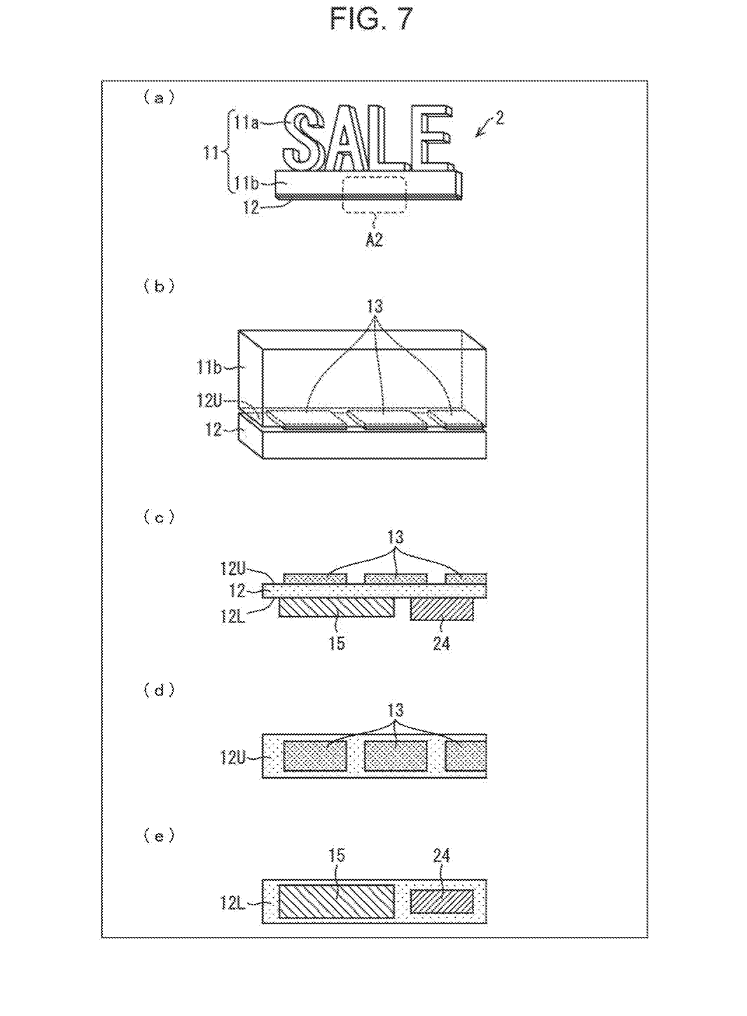

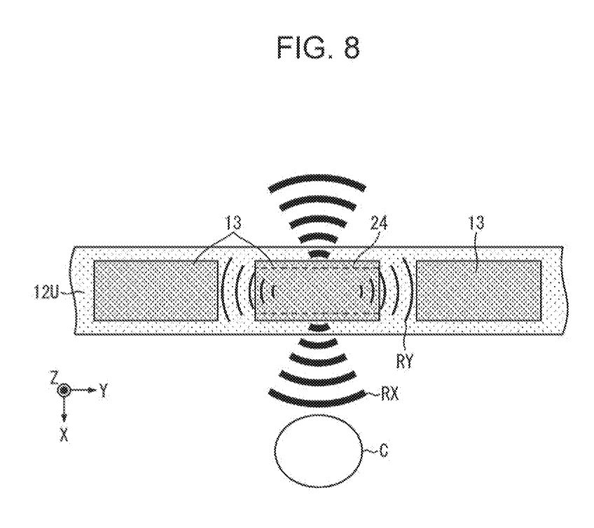

Another embodiment of the invention will be described below with reference to FIGS. 7 and 8. Note that, for convenience of description, members having the same functions as those of the members described in the aforementioned embodiment will be given the same reference signs and description thereof will be omitted.

### (Information Transmitting Apparatus 2)

An information transmitting apparatus 2 of the present embodiment has a configuration obtained by replacing the antenna 14 with an antenna 24 in the information transmitting apparatus 1 of Embodiment 1 described above.

FIGS. 7(a) to (e) each illustrates the configuration of the information transmitting apparatus 2. FIG. 7(a) illustrates an external appearance of the information transmitting apparatus 2 and FIG. 7(b) is an enlarged view of an area A2 in FIG. 7(a).

FIG. 7(c) is a front view of the solar cell mount board 12 in the area A2, FIG. 7(d) is a top view of the solar cell mount board 12 in the area A2, and FIG. 7(e) is a bottom view of the solar cell mount board 12 in the area A2. Note that, for simplification of the illustration, the illustration of the non-advertisement part 11b is omitted in FIGS. 7(c) to (e).

As illustrated in FIGS. 7(c) to (e), in the information transmitting apparatus 2 of the present embodiment, the antenna 24 is arranged on the mount board second surface 12L. That is, the information transmitting apparatus 2 of the present embodiment is different from the information. transmitting apparatus 1 of Embodiment 1 in that the antenna 24 and the BLE module 15 are arranged on the same surface (mount board second surface 12L) of the solar cell mount board 12.

In other words, the information transmitting apparatus 2 of the present embodiment may be interpreted as being obtained by arranging the antenna on the surface (mount board second surface 12L) of the solar cell mount board 12, on which the BLE module 15 is arranged, in the information transmitting apparatus 1 of Embodiment 1.

According to the information transmitting apparatus 2 of the present embodiment, by arranging the antenna 24 on the mount board second surface 12L, the antenna is able to be mechanically protected by the fluorescent concentrating plate 11 (non-advertisement part 11b).

Thus, it is possible to reduce possibility that when the customer puts the mobile terminal 1000 close to the information transmitting apparatus 2, the mobile terminal 1000 contacts the antenna 24 so that the antenna 24 is broken. In this manner, the information transmitting apparatus 2 of the present embodiment has a suitable configuration for mechanically protecting the antenna 24.

Moreover, in the information transmitting apparatus 2, by arranging the antenna 24 on the mount board second surface 12L, a length in a short side direction of the solar cell mount board 12 is able to be made shorter than that of Embodiment 1. More specifically, the length in the short side direction of the solar cell mount board 12 is able to be almost similar to a length in a depth direction (an X direction of FIG. 8 described below) of the fluorescent concentrating plate 11.

Thus, most of the solar cell mount board 12 is able to be covered with the fluorescent concentrating plate 11 (non-advertisement part 11b). Accordingly, the solar cell mount board 12 becomes difficult to be visually recognized by the customer C, so that visibility of the advertisement part 11a that functions as the POP advertisement is able to be improved.

Subsequently, directivity of intensity of a radio wave emitted from the information transmitting apparatus 2 will be described with reference to FIG. 8. FIG. 8 is a view (top view) schematically illustrating directivity of intensity of a radio wave emitted from the antenna 24. Note that, the directivity of the radio wave intensity similar to FIG. 8 is realized also in Embodiment 1 described above and each embodiment described below.

In FIG. 8, a direction from the antenna 24 to the customer C is referred to as the X direction. The X direction may be interpreted as a short side direction of the mount board first surface 12U (solar cell mount board 12). Note that, the X direction may be also interpreted as the depth direction (thickness direction) of the information transmitting apparatus 2 (and the fluorescent concentrating plate 11).

A direction vertical to the X direction is referred to as a Y direction. The Y direction may be interpreted as a long side direction (longitudinal direction) of the mount board first surface 12U (solar cell mount board 12). Note that, the Y direction may be also interpreted as a width direction (longitudinal direction) of the information transmitting apparatus 2 (and the fluorescent concentrating plate 11). When a plurality of information transmitting apparatuses 2 are provided and used as POP advertisements, the plurality of information transmitting apparatuses 2 are arranged in parallel along the Y direction (refer to FIG. 4 described above).

A direction vertical to the X direction and Y direction described above is referred to as a Z direction. The Z direction may be interpreted as a height direction of the information transmitting apparatus 2 (and the fluorescent concentrating plate 11). When the information transmitting apparatus according to an aspect of the invention is used as the POP advertisement, the advertisement part 11a is formed to have a significantly larger size in the Y direction and the Z direction compared to the X direction.

As an example, in the information transmitting apparatus 2, the advertisement part 11a has a dimension in the X direction of 2 mm, a dimension in the Y direction of 30 cm, and a dimension in the Z direction of 50 cm. In this manner, the dimension in the X direction of the advertisement part 11a is about a few mm and is relatively small. On the other hand, the dimensions in the Y direction and the Z direction are about several tens cm and are significantly larger than the dimension in the X direction.

Note that, in the fluorescent concentrating plate 11, a dimension in the X direction of the non-advertisement part 11b is almost equal to the dimension in the X direction of the advertisement part 11a. This is because the advertisement part 11a and the non-advertisement part 11b are formed by cutting out fluorescent concentrating plate in a plate shape as described above.

Here, in FIG. 8, a radio wave directed to the X direction of radio waves emitted from the antenna 24 is referred to as a radio wave RX (radio signal). A radio wave directed to the Y direction of the radio waves emitted from the antenna 24 is referred to as a radio wave RY (radio signal).

As illustrated in FIG. 8, with the information transmitting apparatus according to an aspect of the invention, the intensity of the radio wave RY is able to be made sufficiently smaller than the intensity of the radio wave RX. A reason therefor will be described below.

As described above, the dimension (2 mm) in the x direction of the advertisement part 11a is sufficiently smaller than the dimension (30 cm) in the Y direction of the advertisement part 11a. Thus, an extent that the radio wave RX is obstructed by the fluorescent concentrating plate 11 is sufficiently small compared to the radio wave RY. That is, the radio wave RX is hardly obstructed by the fluorescent concentrating plate 11. On the other hand, most of the radio wave RY is obstructed by the fluorescent concentrating plate 11.

In this manner, with the information transmitting apparatus (for example, the information transmitting apparatus 2) according to an aspect of the invention, the intensity of the radio wave RX directed to the X direction (the direction from the information transmitting apparatus 2 to the customer C) is able to be sufficiently increased and the intensity of the radio wave RY directed to the Y direction (the direction in which the plurality of information transmitting apparatuses are arranged in parallel) is able to be sufficiently reduced.

Thus, the intensity of a radio wave directed from a different information transmitting apparatus adjacent to the information transmitting apparatus 2 to the customer C is abler to be sufficiently reduced. Accordingly, it is possible to prevent the customer C from acquiring product related information that is not intended to be acquired by the customer C from the different information transmitting apparatus. As a result, an effect is exerted that the customer C is enabled to more reliably acquire only product related information that intended to be acquired by the customer C.

### Embodiment 3

Another embodiment of the invention will be described below with reference to FIG. 9. Note that, for convenience of description, members having the same functions as those of the members described in the aforementioned embodiments will be given the same reference signs and description thereof will be omitted.

### (Information Transmitting Apparatus 3)

An information transmitting apparatus 3 of the present embodiment has a configuration obtained by replacing (i) the non-advertisement part 11b with a non-advertisement part 31b and (ii) the antenna 14 with an antenna 34 in the information transmitting apparatus 1 of Embodiment 1 described above. Note that, a fluorescent concentrating plate having the advertisement part 11a and the non-advertisement part 31b is referred to as a fluorescent concentrating plate 31 in the present embodiment.

FIGS. 9(a) to (e) each illustrates the configuration of the information transmitting apparatus 3. FIG. 9(a) Illustrates an external appearance of the information transmitting apparatus 3 and FIG. 9(b) is an enlarged view of an area A3 in FIG. 9(a).

FIG. 9(c) is a front view of the solar cell mount board 12 in the area A3, FIG. 9(d) is a top view of the solar cell mount board 12 in the area A3, and FIG. 9(e) is a bottom view of the solar cell mount board 12 in the area A3. Note that, for simplification of the illustration, the illustration of the non-advertisement part 31b is omitted in FIGS. 9(c) to (e).

As illustrated in FIG. 9(b), a recess 31bb as a space in which the antenna 34 is housed is formed at an end surface (end) of the non-advertisement part 31b. That is, the non-advertisement part 31b of the present embodiment may be interpreted as being obtained by adding the recess 31bb to the non-advertisement part 11b of Embodiment 1.

The antenna 34 is provided inside the recess 31bb in the information transmitting apparatus 3 of the present embodiment. That is, as illustrated in FIGS. 9(b) to (e), the antenna 34 is arranged on the mount board first surface 12U.

In other words, the information transmitting apparatus 3 of the present embodiment may be interpreted as being obtained by providing the recess 31bb, in which the antenna 4 is arranged on the mount board first surface 12U, in the information transmitting apparatus 1 of Embodiment 1.

According to the information transmitting apparatus 3 of the present embodiment, since the antenna 34 is housed inside the recess 31bb (that is, inside the fluorescent concentrating plate 31), even when the antenna 34 is arranged the mount board first surface 12U, the antenna is able to be mechanically protected by the fluorescent concentrating plate 31.

Thus, the information transmitting apparatus 3 of the present embodiment is also makes it possible to reduce possibility that when the customer C puts the mobile terminal 1000 close to the information transmitting apparatus 3, the mobile terminal 1000 contacts the antenna 34 so that the antenna 24 is broken. In this manner, the information transmitting apparatus 3 of the present embodiment also has a suitable configuration for mechanically protecting the antenna 34.

Moreover, the antenna 34 is sealed by the fluorescent concentrating plate 11 in the information transmitting apparatus 3 of the present embodiment. This makes it possible to prevent the antenna 34 from becoming corroded being affected by moisture in the atmosphere or the like.

Moreover, in the information transmitting apparatus 3, by housing the antenna 34 inside the recess 31bb, the length in the short side direction of the solar cell mount board 12 is able to be made shorter compared to Embodiment 1 similarly to Embodiment 2 described above. Thus, the information transmitting apparatus 3 of the present embodiment also makes it possible to improve visibility of the advertisement part 11a.

### Embodiment 4

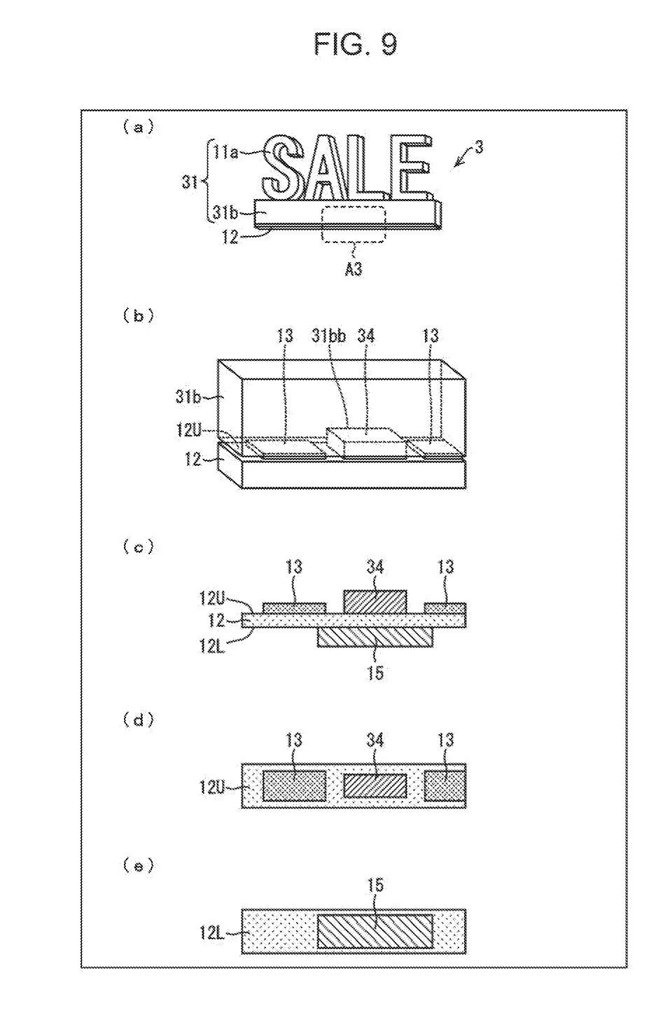

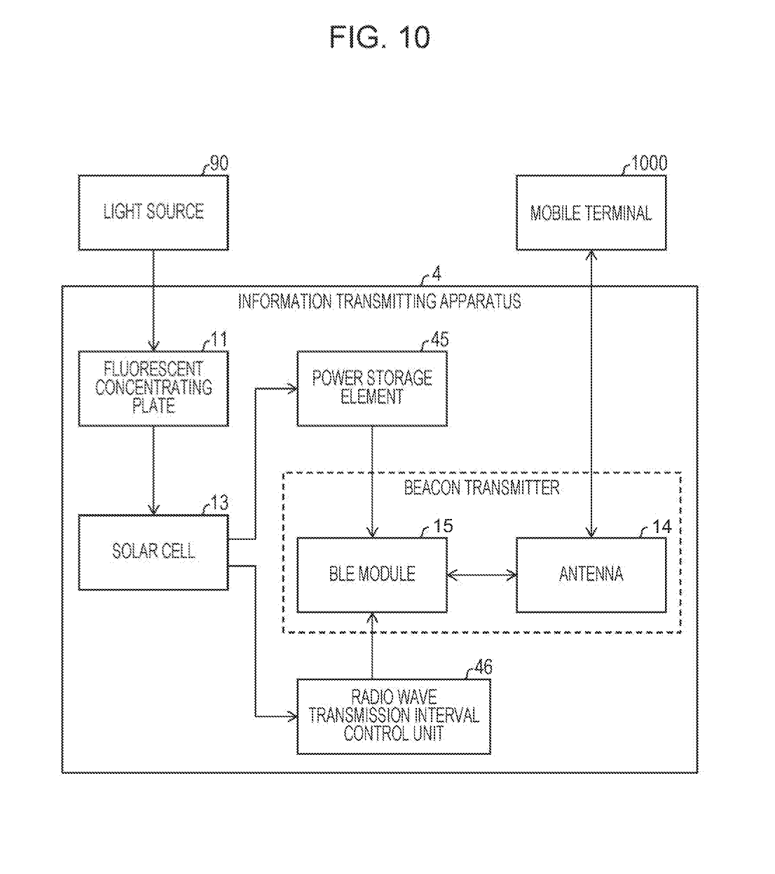

Another embodiment of the invention will be described below with reference to FIGS. 10 and 11. Note that, for convenience of description, members having the same functions as those of the members described in the aforementioned embodiments will be given the same reference signs and description thereof will be omitted.

### (Information Transmitting Apparatus 4)

FIG. 10 is a functional block diagram illustrating a configuration of a main part of an information transmitting apparatus 4 or the present embodiment. In the present embodiment, description will be given by assuming that the information transmitting apparatus 4 has a configuration obtained by adding a power storage element 45 and a radio wave transmission interval control unit 46 (power consumption management unit) to the information transmitting apparatus 1 of Embodiment 1. However, the power storage element 45 and the radio wave transmission interval control unit 46 of the present embodiment may be added to the information transmitting apparatus according to other embodiments (Embodiments 2 and 3 described above or Embodiments 5 and 6 described below).

The power storage element 45 is an element for storing power generated by the solar cell 13. The power storage element 45 may be a capacitive element, for example, such as an electric double layer capacitor or an electrolytic capacitor. Note that, as the power storage element 45, a secondary battery, for example, such as a lithium ion battery, a nickel-hydrogen battery, a nickel-cadmium battery, or a storage battery is also able to be used.

However, from a viewpoint of reduction in a size of the power storage element 45, the capacitive element is preferably used as the power storage element 45.

When the capacitive element is used as the power storage element 45, it is possible to achieve less reduction in storage capacity caused by the number (the number of cycles) of times of repeating (i) charging by power generation of the solar cell 13 and (ii) discharging by an operation of the BLE module 15 (that is, the transmitting unit). Thus, it becomes possible to improve product life of the information transmitting apparatus 4.

The power storage element 45 provides the BLE module 15 with stored power. That is, in the present embodiment, the BLE module 15 (that is, the transmitting unit) is operated with the power supplied from the power storage element 45.

In this manner, even when the power that is able to be generated by the solar cell 13 is temporarily reduced (for example, when illuminance of fluorescent light received by the solar cell 13 is temporarily reduced) due to the power being supplied from the power storage element 45 to the BLE module 15, the operation of the BLE module 15 is able to be continued by using the power stored by the power storage element 45.

However, in the present embodiment, power consumption of the BLE module 15 (that is, the transmitting unit) is managed by the radio wave transmission interval control unit 46 as indicated below. Thus, the power storage element 45 does not need to be always provided. When the power storage element 45 is not provided, the power is supplied from the solar cell 13 to the BLE module 15 as described above.

The radio wave transmission interval control unit 46 has a function of controlling a transmission interval of a radio wave R transmitted from the beacon transmitter. The radio wave transmission interval control unit 46 controls the transmission interval of the radio wave R by controlling the operation of the BLE module 15.

In the present embodiment, a case where the radio wave R is transmitted as a periodic signal (for example, a pulse signal) is considered. The radio wave transmission interval control unit 46 controls the transmission interval of the radio wave R by controlling a period of a periodic signal (high-frequency signal) provided from the BLE module 15 to the antenna 14.

Here, the transmission interval of the radio wave R means a temporal period of the radio wave R (radio signal) that is regularly transmitted from the beacon transmitter. When the radio wave R is transmitted as a pulse signal, the transmission period of the radio wave R is prescribed as time from when a certain pulse signal waveform rises to when a next pulse signal waveform rises.

Note that, in a general beacon transmitter, a transmission interval at which a radio wave as a pulse signal is transmitted is 0.1 second. Note that, the transmission interval of the radio wave R described above is equal to a period of a periodic signal modulated by the BLE module 15.

The radio wave transmission interval control unit 46 detects a value of a voltage V output from the solar cell 13. Then, the radio wave transmission interval control unit 46 calculates a temporal change of illuminance of light (fluorescent light) received by the solar cell 13 in accordance with a temporal change of the value of the voltage V.

The value of the voltage V output from the solar cell 13 generally depends on the illuminance of the (fluorescent light) received by the solar cell 13. Thus, when a correspondence relation between (i) the value of the voltage V and (ii) the illuminance of the fluorescent received by the solar cell 13 in the solar cell 13 is known, from the value of the voltage V at a certain time, the illuminance of the fluorescent light at the time is able to be calculated.

Accordingly, by setting in advance a numerical table (numerical scheme) indicating the correspondence relation described above to the radio wave transmission interval control unit 46, the illuminance of the fluorescent light L2 at each time is able to be calculated by the radio wave transmission interval control unit 46.

In this manner, the radio wave transmission interval control unit 46 is able to calculate a temporal change of the illuminance of the fluorescent light. The radio wave transmission interval control unit 46 generates illuminance information that is information indicating temporal change of the illuminance of the fluorescent light.

Subsequently, the radio wave transmission interval control unit 46 controls the transmission interval of the radio wave R on the basis of the generated illuminance information. An operation of the radio wave transmission interval control unit 46 will be described below with reference to FIGS. 11(a) and (b).

FIG. 11(a) is a graph indicating an example of a temporal change (content of illuminance information) of illuminance of light (fluorescent light) received by the solar cell 13. In the graph of FIG. 11(a), a horizontal axis indicates a time and a vertical axis indicates illuminance of fluorescent light received by the solar cell 13. Hereinafter, each of times T1 to T6 illustrated to FIG. 11(a) will be described on the basis of (A1) to (A6) described below.

(A1) The time T1 is a time during which the customer C is not present around the information transmitting apparatus 4. In the time T1, the illumination light directed to the fluorescent concentrating plate 11 is not blocked by the customer C. Thus, the illuminance of the fluorescent light has an almost fixed and relatively large value regardless of lapse of time.

(A2) The time T2 is a time during which the customer C approaches the information transmitting apparatus 4 after the time T1. In the time T2, the illumination light directed to the fluorescent concentrating plate 11 is more notably blocked by the customer C as the customer C approaches the information transmitting apparatus 4. Thus, the illuminance of the fluorescent light is reduced as the customer C approaches the information transmitting apparatus 4.

(A3) The time T3 is a time during which the customer C browses the product G in front of the information transmitting apparatus 4 after the time T2. In the time T3, a positional relation between the customer and the information transmitting apparatus 4 is almost fixed. Thus, the illuminance of the fluorescent light has an almost fixed and relatively small value regardless of lapse of time.

(A4) The time T4 is a time during which the customer C puts the mobile terminal 1000 close to the information transmitting apparatus 4 after the time T3. In the time T4, the illumination light directed to the fluorescent concentrating plate 11 is blocked not only by the customer C but also by the mobile terminal 1000.

The illumination light is more notably blocked by the mobile terminal 1000 as the mobile terminal 1000 approaches the information transmitting apparatus 4. Thus, the illuminance of the fluorescent light is reduced as the mobile terminal 1000 approaches the information transmitting apparatus 4.

Note that, after product related information is acquired from the information transmitting apparatus 4 by the mobile terminal 1000, the customer C puts the mobile terminal 1000 away from the information transmitting apparatus 4. Thus, the illuminance of the fluorescent light increases as the mobile terminal 1000 is away from the information transmitting apparatus 4.

(A5) The time T5 is a time during which the customer C leaves the front of the information transmitting apparatus 4 (in other words, the product G) after the time T4. The illuminance of the fluorescent light increases as the customer C is away from the information transmitting apparatus 4.

(A6) The time T6 is a time during which the customer C is not present around the information transmitting apparatus 4 after the time T5. A temporal change of the illuminance of the fluorescent light in the time T6 is similar to that of the case of the time T1 described above.

An amount of the power generated by the solar cell 13 depends on the illuminance of the fluorescent light described above. Accordingly, when the illuminance of the fluorescent light is sufficiently large, sufficient power is able to be supplied from the power storage element 45 to the BLE module 15.

The power consumption of the beacon transmitter generally depends on the transmission interval of the radio wave. Specifically, the power consumption of the beacon transmitter increases as the transmission interval of the radio wave becomes shorter. Thus, in a case where the transmission interval of the radio wave remains short when the illuminance of the fluorescent light is reduced, it is concerned that the power for operating the beacon transmitter (that is, power for continuously causing the beacon transmitter to transmit the radio wave) exceeds the power generated by the solar cell 13.

In order to deal with such a problem, the radio wave transmission interval control unit 46 is configured to adjust (change) the transmission interval of the radio wave R on the basis of the illuminance information corresponding to FIG. 11(a) describe above. FIG. 11(b) is a graph indicating a temporal change of the transmission interval of the radio wave R. In the graph of FIG. 11(b), a horizontal axis indicates a time and indicates a transmission interval of the radio wave R.

As illustrated in FIG. 11(b), the transmission interval of the radio wave R is controlled on the basis of the aforementioned illuminance information (in other words, a temporal change of the illuminance of the fluorescent light). With reference to FIG. 11(b), an example of the operation of the radio wave transmission interval control unit 46 is as indicated with following (B1) to (B6).

(B1) The radio wave transmission interval control unit 46 sets the transmission interval of the radio wave R to “0.1 second” in the times T1 and T6. When the illuminance of the fluorescent light is sufficiently high, sufficient power is able to be supplied from the power storage element 45 to the beacon transmitter and the transmission interval of the radio wave R is able to be set to be at the same degree as a transmission interval of a general beacon transmitter.

(B2) The radio wave transmission interval control unit 46 sets the transmission interval of the radio wave R to “1 second” in the times T2 and T3. For example, when the illuminance of the fluorescent light becomes lower than a predetermined value, the radio wave transmission interval control unit 46 may set the transmission interval of the radio wave R to be longer.

Thereby, even when the power generated by the solar cell 13 is reduced, the beacon transmitter is able to be operated by the power supplied from the power storage element 45. Note that, the transmission interval of the radio wave R is only required to be set so that the power consumption of the BLE module 15 (in other words, the power consumption of the beacon transmitter) is smaller than the power generated by the solar cell 13 with the fluorescent light.

(B3) The radio wave transmission interval control unit 46 sets the transmission interval of the radio wave R to “2 seconds” in the times T4 and T5. For example, when the illuminance of the fluorescent light is particularly reduced, the radio wave transmission interval control unit 46 may further increase the transmission interval of the radio wave R until the illuminance of the fluorescent light exceeds a predetermined value. Thereby, even when the power generated by the solar cell 13 is significantly reduced, the beacon transmitter is able to be operated by the power supplied from the power storage element 45.

In this manner, according to the information transmitting apparatus of the present embodiment, even when the illuminance of the fluorescent light is reduced (that is, when the power generated by the solar cell 13 is reduced), it is possible to continue the operation of the beacon transmitter while reducing the power consumption. Thus, an effect that the customer C is enabled to more reliably acquire product related information is exerted.

Note that, the present embodiment aims to reduce the power consumption of the beacon transmitter in accordance with the reduction of the power that is able to be generated by the solar cell 13. That is, the radio wave transmission interval control unit 46 of the present embodiment may be interpreted as a member (power consumption management unit) provided for managing the power consumption of the beacon transmitter.

Note that, a method for reducing the power consumption of the beacon transmitter is not limited only to a method for increasing the transmission interval of the radio wave R. For example, when the radio wave R is a pulse signal, the power consumption of the beacon transmitter is able to be reduced also by reducing a duty ratio of the radio wave R. Note that, the duty ratio means a ratio of a pulse width relative to a period of a pulse signal waveform.

In addition, also by reducing the intensity of the radio wave R, the power consumption of the beacon transmitter is able to be reduced. Note that, also by reducing an amount of date conveyed by the radio wave R, the power consumption of the beacon transmitter is able to be reduced.

Therefore, the radio wave transmission interval control unit 46 of the present embodiment may be interpreted as a specific example of the power consumption management unit described above. The power consumption management unit is only required to control the operation of the BLE module 15 so that the power consumption of the BLE module 15 is smaller than the power generated by the solar cell 13 receiving the fluorescent light.

### Embodiment 5

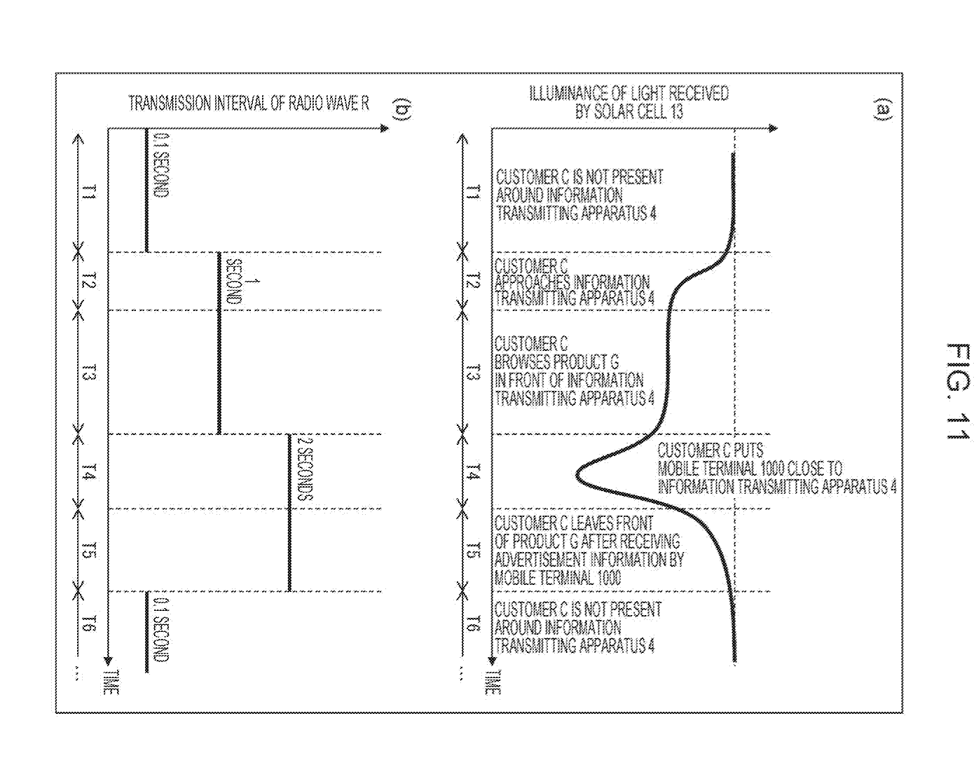

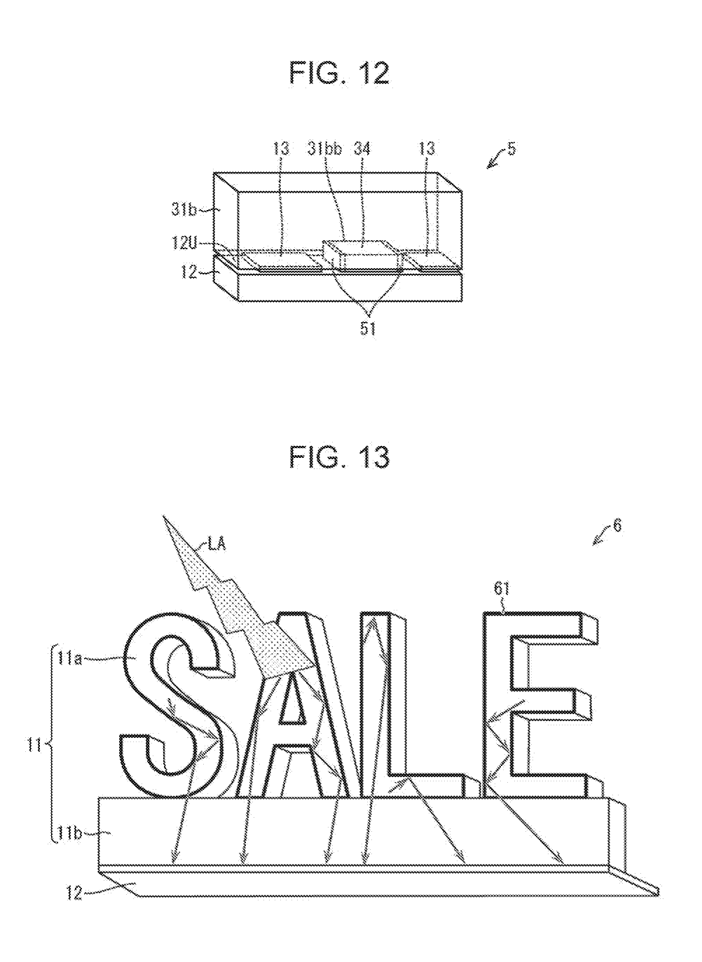

Another embodiment of the invention will be described below with reference to FIG. 12. Note that, for convenience of description, members having the same functions as those of the members described in the aforementioned embodiments will be given the same reference signs and description thereof will be omitted.

### (Information Transmitting Apparatus 5)

FIG. 12 illustrates a configuration of an information transmitting apparatus 5 of the present embodiment. The information transmitting apparatus 5 of the present embodiment has a configuration obtained by adding a metal film 51 to the information transmitting apparatus 3 of Embodiment 3 described above. As illustrated in FIG. 12, the metal film 51 is arranged on an inner surface provided in the Y direction (the longitudinal direction of the fluorescent concentrating plate 31) in the recess 31bb.

Since a metal material has characteristics of suitably absorbing a radio wave, by providing the metal film 51, the radio wave RY directed to the Y direction is able to be absorbed by the metal film, thus making it possible to further reduce the intensity of the radio wave RY (refer to FIG. 8 described above).

### Embodiment 6

Another embodiment of the invention will be described below with reference to FIG. 13. Note that, for convenience of description, members having the same functions as those of the members described in the aforementioned embodiments will be given the same reference signs and description thereof will be omitted.

### (Information Transmitting Apparatus 6)

FIG. 13 illustrates a configuration of an information transmitting apparatus 6 of the present embodiment. The information transmitting apparatus 6 of the present embodiment has a configuration obtained by providing a metal film 61 in at least a part of an edge of the fluorescent concentrating plate in the information transmitting apparatus according to any of Embodiments 1 to 5 described above.

FIG. 13 illustrates a configuration in which the metal film 61 is provided on a whole of the edge of the advertisement part 11a in the fluorescent concentrating plate 11, as an example. That is, in the advertisement part 11a, the metal film 61 is provided so as to border the edge having shapes corresponding to four characters “S”, “A”, “L” and “E”.

However, the metal film 61 may be provided only in a part of the advertisement part 11a. For example, the metal film 61 may be provided so as to border only the edge having the shape corresponding to one character “A” in the advertisement part 11a. Note that, the metal film 61 may be provided on an edge of the non-advertisement part 11b.

When the metal film 61 is provided, the fluorescent light directed to the outside of the fluorescent concentrating plate 11 is able to be reflected toward the inside of the fluorescent concentrating plate 11 by the metal film 61. This makes it possible to make a greater amount of fluorescent light incident on the solar cell 13, so that the power that is able to be generated by the solar cell 13 is able to be increased. Moreover, since the radio wave RY directed to the Y direction is able to be absorbed by the metal film 61, the intensity of the radio wave RY is able to be further reduced.

Additionally, when the metal film 61 is provided in at least a part of the edge of the advertisement part 11a, it becomes easier for the customer C to visually recognize the advertisement part 11a. Thus, a function of the advertisement part 11a as a POP advertisement is also able to be promoted.

### Conclusion

An information transmitting apparatus (1) according to an aspect 1 of the invention is an information transmitting apparatus that transmits product related information, including: a transmitting unit (antenna 14 and BLE module 15) that transmits the product related information as a radio signal (radio wave R); a fluorescent concentrating plate (11) that emits fluorescent light upon reception of incident light (LA, LB) from both surfaces of at least a front surface (non-advertisement part second surface 11bB) and a back surface (non-advertisement part first surface 11bA) and guides the fluorescent light; and a solar cell (13) that provides the transmitting unit with power generated upon reception of the fluorescent light, in which the fluorescent concentrating plate functions as at least a part of a POP advertisement for a product (G), and the solar cell is arranged at an end of the fluorescent concentrating plate so as to be able to receive the fluorescent light.

According to the aforementioned configuration, a fluorescent concentering solar cell that is constituted by the fluorescent concentering plate and the solar cell is able to be adopted as a power source of the information transmitting apparatus. Thus, even when the customer C puts the mobile terminal 1000 close to the information transmitting apparatus 1 to acquire product related information from the information transmitting apparatus 1 as illustrated in FIG. 3 described above, power generation by the solar cell is able to be performed.

This is because, as described above, even when the incident light (incident light LB) incident on the front surface of the fluorescent concentrating plate (that is, the POP advertisement) is blocked by the customer C (and the mobile terminal 1000), the incident light (incident light LA) emitted from a light source on a side opposite to a position of the customer C is able to be received by the back surface of the fluorescent concentrating plate.

Thus, even when a part of the light incident on the POP advertisement is blocked by the customer, sufficient power for operating the transmitting unit (beacon transmitter) is able to be supplied from the solar cell to the transmitting unit. As a result, an effect is exerted that the customer is enabled to preferentially acquire product related information desired by the customer even when a part of the light incident on the POP advertisement is blocked by the customer.

In the information transmitting apparatus according to an aspect 2 of the invention, it is preferable that a modulation unit (BLE module 15) that modulates the product related information to a periodic signal and an antenna (14) that transmits the periodic signal as the radio signal are included, and the solar cell, the modulation unit, and the antenna are provided on the same mount board (solar cell mount board 12) in the aspect 1.

According to the aforementioned configuration, widths of wirings (for example, the power source wiring 17 and the antenna wiring 18 of FIG. 3) by which the solar cell and the beacon transmitter (the modulation unit and the antenna) are connected are able to be made relatively small. Thus, a radio signal transmitted from the antenna is less likely to be affected by noise by the wirings, so that radio wave intensity of the radio signal is able to be set to be relatively low.

As a result, an effect is exerted that even when a plurality of information transmitting apparatuses (information transmitting apparatuses 1A to 1C) are arranged so as to correspond to a plurality of products (products GA to GC) as illustrated in FIG. 4 described above, the customer is enabled to selectively acquire only product related information that is intended to be acquired by the customer. For example, as illustrated in FIG. 4, the customer C is able to acquire desired product related information only from the closest information transmitting apparatus 1B.

Further, in the information transmitting apparatus according to an aspect of the invention, in the fluorescent concentrating plate, the advertisement part serving as a part functioning as at least a part of the POP advertisement is formed so that a dimension in a Y direction is significantly greater than a dimension in an X direction. Here, the X direction is a direction from the antenna to the customer (a short side direction of the mount board) and the Y direction is a direction (a longitudinal direction of the mount board, a longitudinal direction of the information transmitting apparatus) in which a plurality of information transmitting apparatuses are arranged in parallel (refer to FIG. 8 and the like described above).

Accordingly, as illustrated in FIG. 8, for example, intensity of a radio signal (radio wave RX) directed to the X direction is able to be sufficiently increased and intensity of a radio signal (radio wave RY) directed to the Y direction is able to be sufficiently reduced. As a result, an effect is exerted that the customer is enabled to more reliably acquire only product related information that is intended to be acquired by the customer.

In the information transmitting apparatus according to an aspect 3 of the invention, it is preferable that among surfaces of the mount board, a surface facing the end is a first surface (mount board second surface 12U) and a surface opposite to the first surface is a second surface (mount board second surface 12L), and the solar cell is arranged on the first surface, and the modulation unit and the antenna are arranged on the second surface in the aspect 2.

According to the aforementioned configuration, by arranging the antenna on the second surface, the antenna is able to mechanically protected by the fluorescent concentrating plate. As a result, an effect is exerted that it is possible to reduce possibility that when the customer puts the mobile terminal close to the information transmitting apparatus, the mobile terminal contacts the antenna so that the antenna is broken.

In the information transmitting apparatus according to an aspect 4 of the invention, it is preferable that among surfaces of the mount board, a surface facing the end is a first surface and a surface opposite to the first surface is a second surface, and the solar cell and the antenna are arranged on the first surface, the modulation unit is arranged on the second surface, and the antenna is housed inside a recess (31bb) formed at the end of the fluorescent concentrating plate in the aspect 2.

According to the aforementioned configuration, since the antenna is housed inside the recess, that is, inside the fluorescent concentrating plate, an effect is exerted that also when the antenna is arranged on the first surface, the antenna is able to be mechanically protected. As a result, similarly to the aspect 3 described above, an effect is exerted that it is possible to reduce possibility that the antenna is broken. Further since the antenna is sealed by the fluorescent concentrating plate, an effect is exerted that the antenna is able to be prevented from becoming corroded being affected by moisture in the atmosphere or the like.

In the information transmitting apparatus according to an aspect 5 of the invention, it is preferable that when a longitudinal direction of the first surface or the second surface is a longitudinal direction of the fluorescent concentrating plate, a metal film (51) is provided on an inner surface provided in the longitudinal direction of the fluorescent concentrating plate in the recess in the aspect 4.

According to the aforementioned configuration, since the radio signal (that is, the radio wave RY) directed to the Y direction described above is able to be absorbed by the metal film, an effect that the intensity of the radio wave RY is able to be further reduced is exerted.

It is preferable that the information transmitting apparatus according an aspect 6 of the invention further includes a power consumption management unit (radio wave transmission interval control unit 46) that manages power consumption of the transmitting unit, in which the power consumption management unit controls an operation of the transmitting unit so that the power consumption is smaller than the power generated by the solar cell on the basis of a temporal change of illuminance of the fluorescent light received by the solar cell in any one of the aspects 1 to 5.

According to the aforementioned configuration, even when the illuminance of the fluorescent light is reduced (that is, when the power generated by the solar cell is reduced), an operation of the transmitting unit is able to be continued while reducing the power consumption. As a result, an effect is exerted that the customer is enabled to more reliably acquire product related information.

In the information transmitting apparatus according to an aspect 7 of the invention, it is preferable that the radio signal is transmitted as a periodic signal and the power consumption management unit adjusts a period of the radio signal so that the power consumption is smaller than the power generated by the solar cell in the aspect 6.

According to the aforementioned configuration, an effect is exerted that even when the illuminance of the fluorescent light is reduced, by making the period of the radio signal (that is, an oscillation interval of the radio wave) longer, the power consumption is able to be reduced.

It is preferable that the information transmitting apparatus according an aspect 8 of the invention further includes a power storage element (45) that stores the power generated by the solar cell and provides the transmitting unit with the power that is stored in any one of the aspects 1 to 7.

According to the aforementioned configuration, an effect is exerted that even when an amount of the power that is able to be generated by the solar cell is temporarily reduced, the operation of the transmitting unit is able to be continued by using the power stored by the power storage element.

In the information transmitting apparatus according to an aspect 9 of the invention, it is preferable that the power storage element is a capacitive element in the aspect 8.

According to the aforementioned configuration, an effect is exerted that a size of the power storage element is able to be reduced compared to a case where a secondary battery is adopted as the power storage element. Further, an effect is exerted that it is possible to achieve less reduction in storage capacity caused by the number (the number of cycles) of times of repeating (i) charging by power generation of the solar cell and (ii) discharging by an operation of the transmitting unit, thus making it possible to improve a product life of the information transmitting apparatus.

In the information transmitting apparatus according to an aspect 10 of the invention, it is preferable that a metal film (61) is provided on at least a part of an edge of the fluorescent concentrating plate in any one of the aspects 1 to 9.

According to the aforementioned configuration, since the fluorescent light directed to the outside of the fluorescent concentrating plate is able to be reflected toward the inside of the fluorescent concentrating plate by the metal film, the power that is able to be generated by the solar cell is able to be increased. Moreover, since the radio signal (radio wave RY) directed to the Y direction described above is able to be absorbed by the metal film, an effect is exerted that the intensity of the radio wave RY is able to be further reduced.

Additionally, when the metal film is provided in the advertisement part of the fluorescent concentrating plate, it becomes easier for the customer to visually recognize the advertisement part, thus making it also possible to promote a function of the fluorescent concentrating plate as the POP advertisement.

### [Additional Matter]

The invention is not limited to the embodiments described above and may be modified in various manners within the scope of the claims, and an embodiment achieved by appropriately combining technical means disclosed in different embodiments is also encompassed in the technical scope of the invention. Further, by combining the technical means disclosed in each of the embodiments, a new technical feature may be formed.

### INDUSTRIAL APPLICABILITY

The invention is able to be used for an information transmitting apparatus.

### REFERENCE SIGNS LIST

1, 1A, 1B, 1C, 2, 3, 4, 5, 6 information transmitting apparatus

11, 31 fluorescent concentering plate

11bA non-advertisement part first surface (back surface)

11bB non-advertisement part second surface (front surface)

12 solar cell mount board (mount board)

12U mount board first surface (first surface)

12L mount board second surface (second surface)

13 solar cell

14, 24, 34 antenna (transmitting unit)

15 BLE module (transmitting unit, modulation unit)

31bb recess

45 power storage element

46 radio wave transmission interval control unit (power consumption management unit)

51 metal film

61 metal film

G, GA, GB, GC product

LA, LB illumination light light)

R, RA, RB, RC, RX, RY radio wave (radio signal)

1. An information transmitting apparatus that transmits product related information, comprising:
a transmitting unit that transmits the product related information as a radio signal;
a fluorescent concentrating plate that emits fluorescent light upon reception of incident light from both surfaces of at least a front surface and a back surface and guides the fluorescent light; and
a solar cell that provides the transmitting unit with power generated upon reception of the fluorescent light, wherein
the fluorescent concentrating plate functions as at least a part of a POP advertisement for a product, and
the solar cell is arranged at an end of the fluorescent concentrating plate to be able to receive the fluorescent light.

2. The information transmitting apparatus according to claim 1, wherein the transmitting unit includes:
a modulation unit that modulates the product related information to a periodic signal; and
an antenna that transmits the periodic signal as the radio signal, and
the solar cell, the modulation unit, and the antenna are provided on the same mount board.

3. The information transmitting apparatus according to claim 2, wherein among surfaces of the mount board,
a surface facing the end is a first surface and
a surface opposite to the first surface is a second surface, and
the solar cell and the antenna are arranged on the first surface,
the modulation unit is arranged on the second surface, and
the antenna is housed inside a recess formed at the end of the fluorescent concentrating plate.

4. The information transmitting apparatus according to claim 3, wherein
when a longitudinal direction of the first surface or the second surface is a longitudinal direction of the fluorescent concentrating plate,
a metal film is provided on an inner surface provided in the longitudinal direction of the fluorescent concentrating plate in the recess.

5. The information transmitting apparatus according to claim 1, further comprising:
a power consumption management unit that manages power consumption of the transmitting unit, wherein
the power consumption management unit controls an operation of the transmitting unit so that the power consumption is smaller than the power generated by the solar cell on a basis of a temporal change of illuminance of the fluorescent light received by the solar cell.
